(19) United States
(12) Patent Application Publication
(10) Pub. No.: US 2026/0133600 A1
(43) Pub. Date: May 14, 2026

(54) CLOCK SELF-CONTROL CIRCUIT AND CLOCK SIGNAL GENERATION METHOD

(71) Applicant: Realtek Semiconductor Corp., HsinChu (TW)

(72) Inventors: Hui-Tzuen Chen, HsinChu (TW); Hsieh-Han Chiang, HsinChu (TW)

(73) Assignee: Realtek Semiconductor Corp., HsinChu (TW)

(21) Appl. No.: 19/378,355

(22) Filed: Nov. 4, 2025

(30) Foreign Application Priority Data
Nov. 8, 2024 (TW) 113142902

(51) Int. Cl. G06F 1/08; H03K 5/13

(52) U.S. Cl. CPC G06F 1/08; H03K 5/13

(57) ABSTRACT

A clock self-control circuit, comprising: a clock signal generation circuit, configured to generate a target clock signal according to a clock enable signal; and a target circuit, configured to receive the target clock signal, and configured to operate according to the target clock signal and to generate the clock enable signal.

### BACKGROUND OF THE INVENTION

### 1. FIELD OF THE INVENTION

The present invention relates to a clock self-control circuit and a clock signal generation method, and particularly relates to a clock self-control circuit and a clock signal generation method which can trigger the generation of required clock signals.

2. DESCRIPTION OF THE PRIOR ART

In conventional circuits, a clock gating circuit is always used to stop the generation of a clock signal to reduce the power consumption of the circuit. However, conventional clock gating circuits usually cannot be turned off during circuit operations, and therefore cannot stop generating clock signals. Alternatively, the clock gating circuit can be turned off through some complex circuit design methods, but this type of clock gating circuit is usually at the end of the clock tree. In this case, even if the clock gating circuit is turned off, the energy consumption of the circuit that can be reduced is very limited.

### SUMMARY OF THE INVENTION

One objective of the present invention is to provide a clock self-control circuit which can control generation of the clock signal which itself requires.

Another objective of the present invention is to provide a clock signal generation method which can control a clock self-control circuit to generate the clock signal which itself requires.

One embodiment of the present invention discloses a clock self-control circuit, comprising: a clock signal generation circuit, configured to generate a target clock signal according to a clock enable signal; and a target circuit, configured to receive the target clock signal, and configured to operate according to the target clock signal and to generate the clock enable signal.

In one embodiment, the clock self-control circuit further comprises: a timing adjustment circuit, configured to extend a trigger time interval of the clock signal generation circuit, wherein the trigger time interval represents a time interval in which the clock signal generation circuit can be triggered by the clock enable signal. In one embodiment, the timing adjustment circuit is a delay circuit, wherein the target circuit generates the clock enable circuit in a first time period, wherein the first time period has a first predetermined time interval, wherein the timing adjustment circuit controls the clock signal generation circuit to receive the clock enable signal in a second time period after the first time period, wherein a specific signal edge of the clock enable signal triggers generation of the target clock signal in a second predetermined time interval of the second time period.

Another embodiment of the present invention discloses a clock signal generation method, applied to a clock self-control circuit comprising a clock signal generation circuit and a target circuit, comprising: the clock signal generation circuit generating a target clock signal according to a clock enable signal; and the target circuit receiving the target clock signal, operates according to the target clock signal and generates the clock enable signal.

In one embodiment, the clock self-control circuit further comprises a timing adjustment circuit, wherein the clock signal generation method further comprises: the timing adjustment circuit extending a trigger time interval of the clock signal generation circuit, wherein the trigger time interval represents a time interval in which the clock signal generation circuit can be triggered by the clock enable signal. In one embodiment, the timing adjustment circuit is a delay circuit, wherein the clock signal generation method further comprises: the target circuit generating the clock enable circuit in a first time period, wherein the first time period has a first predetermined time interval; the timing adjustment circuit controlling the clock signal generation circuit to receive the clock enable signal in a second time period after the first time period, wherein a specific signal edge of the clock enable signal triggers generation of the target clock signal in a second predetermined time interval of the second time period.

As mentioned above, conventional clock gating circuits cannot be turned off during circuit operation, and thus cannot stop generating clock signals. Alternatively, in order to turn off the clock gating circuit, the clock gating circuit is usually at the end of the clock tree. In this case, even if the clock gating circuit is turned off, the energy consumption of the circuit that can be reduced is very limited. In view of the above embodiments, the self-control circuit provided by the present invention can control the generation of the required clock signal in the functional mode. In this case, the clock gating circuit does not need to be set at the end of the clock tree, so the power consumption can be efficiently reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram illustrating a clock gating circuit according to one embodiment of the present invention.

FIG. 2 is a block diagram illustrating a clock gating circuit according to another embodiment of the present invention.

FIG. 3 is a schematic diagram illustrating operations of the clock gating circuit shown in FIG. 2, according to one embodiment of the present invention.

FIG. 4 is a flow chart illustrating a clock signal generation circuit according to one embodiment of the present invention.

### DETAILED DESCRIPTION

In the following descriptions, several embodiments are provided to explain the concept of the present application. The term “first”, “second”, “third” in following descriptions are only for the purpose of distinguishing different one components, and do not mean the sequence of the components. For example, a first device and a second device only mean these devices can have the same structure but are different devices.

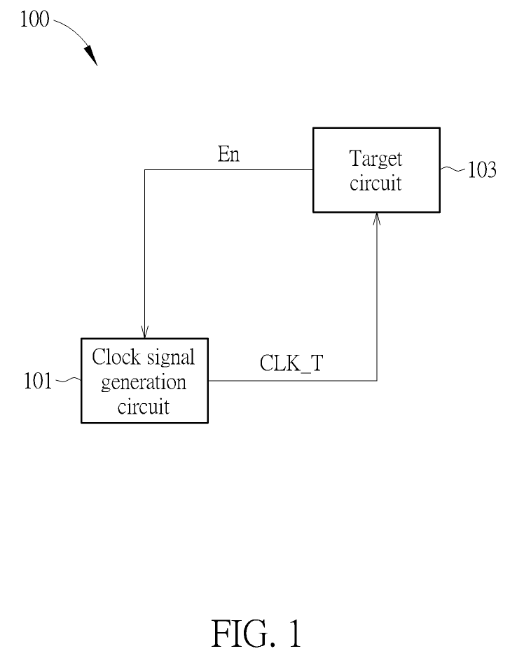

FIG. 1 is a block diagram illustrating a clock gating circuit 100 according to one embodiment of the present invention. As shown in FIG. 1, the clock self-control circuit 100 comprises a clock signal generation circuit 101 and a target circuit 103 . The clock signal generation circuit 101 is configured to generate a target clock signal CLK_T according to a clock enable signal En. The target circuit 103 is configured to receive the target clock signal CLK_T, to operate according to the target clock signal CLK_T and to generate the clock enable signal En. In one embodiment, the clock signal generation circuit 101 is triggered by a specific signal edge (e.g., a negative edge) of the clock enable signal En to start generating the target clock signal CLK_T. In one embodiment, the clock signal generation circuit 101 and the target circuit 103 are located in the same chip or the same IC (Integrated Circuit).

In one embodiment, the clock signal generation circuit 101 is a clock gating circuit. In this case, the clock signal generation circuit 101 can receive an external clock signal and gate the external clock signal to control whether the external clock signal is transmitted to the target circuit 103. When the external clock signal is transmitted to the target circuit 103 , the external clock signal is the target clock signal CLK_T. When the external clock signal is not transmitted to the target circuit 103, it means that the target clock signal CLK_T is not generated.

The target circuit 103 can be any circuit, for example, a memory or an amplifier circuit. In one embodiment, the target circuit 103 comprises a plurality of logic components. In this case, the target circuit 103 may receive a control signal and generate the clock enable signal En according to the logic levels of the control signal through the plurality of logic components. In another embodiment, the target circuit 103 comprises a state machine, and the target circuit 103 generates the clock enable signal En according to a state represented by the state machine. For example, in one embodiment, the target circuit 103 can selectively operate in a functional mode and a non-functional mode. If the state machine represents that the target circuit 103 operates in the functional mode, the target circuit 103 generates the clock enable signal En to control the clock signal generation circuit 101 to generate the target clock signal CLK_T. On the opposite, in the non-functional mode, En is not generated, and the target clock signal CLK_T is not generated.

In one embodiment, in the functional mode, the target circuit 103 operates according to the target clock signal CLK_T (e.g., operates according to the logic levels or signal edges of the target clock signal CLK_T), and can provide its functions normally. For example, if the target circuit 103 is a memory, the target circuit 103 may provide a function of storing data in the functional mode. If the target circuit 103 is an amplifier circuit, the target circuit 103 may provide a signal amplification function in the functional mode. In the non-functional mode, the target circuit 103 does not operate according to the target clock signal CLK_T, and thus does not provide the functions in the functional mode. For example, in a test mode, the target circuit 103 may perform a test operation. For example, the target circuit 103 may receive a test pattern and generate an output signal accordingly. This output signal can be used to confirm whether the target circuit 103 operates correctly. In the test mode, the target circuit 103 may operate according to a test clock signal. The test clock signal and the target clock signal CLK_T are different clock signals and have different parameters, such as different phases or frequencies.

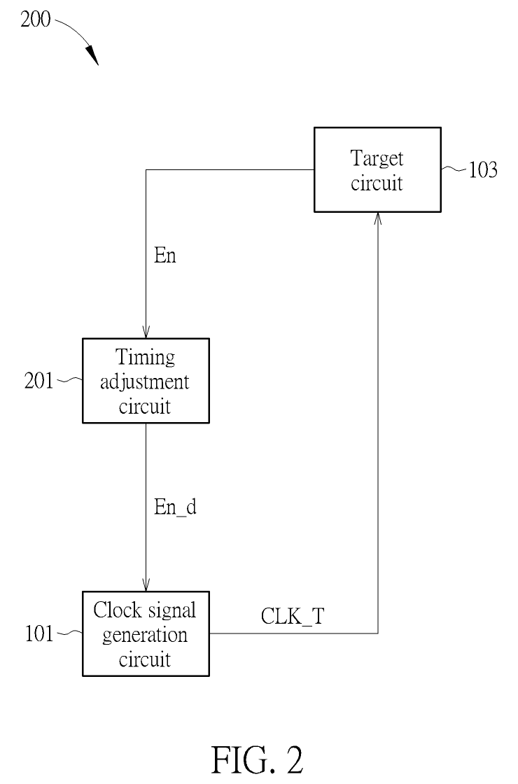

The clock self-control circuit provided by the present invention may comprise other structures. FIG. 2 is a block diagram illustrating a clock gating circuit 200 according to another embodiment of the present invention. As shown in FIG. 2, in addition to the clock signal generation circuit 101 and the target circuit 103 shown in FIG. 1, the clock self-control circuit 200 further comprises a timing adjustment circuit 201 for extending a trigger time interval of the clock signal generation circuit 101. The trigger time interval represents a time interval in which the clock signal generation circuit 101 can be triggered by the clock enable signal En to generate the target clock signal CLK_T.

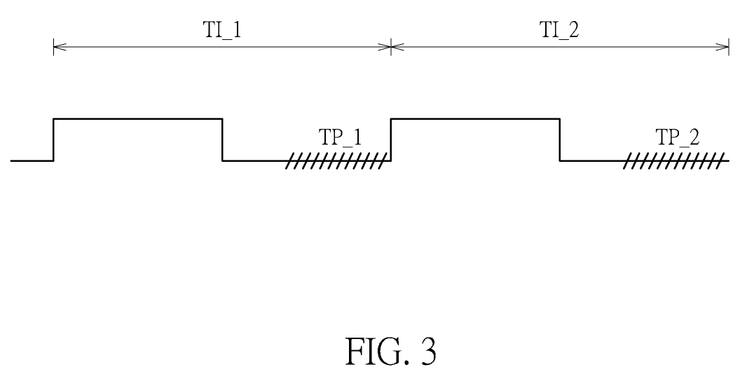

FIG. 3 is a schematic diagram illustrating operations of the clock gating circuit shown in FIG. 2, according to one embodiment of the present invention. The time period and time interval shown in FIG. 3 may be the time period and time interval of any signal used by the clock automatic control circuit 200. In this example, the timing adjustment circuit 201 is a delay circuit, such as a D-type flip-flop. However, the timing adjustment circuit 201 may also be other circuits capable of extending the triggering time interval of the clock signal generation circuit 101. The target circuit 101 generates a clock enable signal En in a first time period TI_1. The first time period TI_1 has a first predetermined time interval TP_1. As mentioned above, the generation of the target clock signal CLK_T can be triggered by the negative edge of the clock enable signal En. In the embodiment of FIG. 1 , the clock enable signal En is generated in the first time period TI_1, and its negative edge must fall within the first predetermined time interval TP_1 of the same time period to correctly trigger the generation of the target clock signal CLK_T. That is, its trigger time interval and the time of the clock enable signal En are in the same time period. In this case, the target circuit 103 must generate a clock enable signal immediately and the components of the clock self-control circuit 100 must not have too much delay, so that the negative edge falls within the first predetermined time interval TP_1 in the same time period.

However, in some cases, the target circuit 103 may not need to receive the target clock signal CLK_T so immediately. In detail, some delay between the time point when the target circuit 103 generates the clock enable signal En and the time point when the target circuit 103 receives the target clock signal CLK_T can be tolerated. Therefore, in the embodiment of FIG. 2 , the timing adjustment circuit 201 delays the clock enable signal En to the clock enable signal En_d (i.e., generates a delayed clock enable signal). The negative edge of the clock enable signal En_d only needs to be received by the clock signal generation circuit 101 within the second predetermined time interval TP_2 of the second time period TI_1 after the first time period TI_1 to correctly trigger the generation of the target clock signal. That is, the trigger time interval is extended to be a predetermined time interval in the next or next N (N is a positive integer) time periods after the time period in which the clock enable signal En is generated. In this way, the target circuit 103 can have more time to generate the clock enable signal En, and the clock enable signal En has a higher tolerance to the delay of each component or path of the clock automatic control circuit 200 .

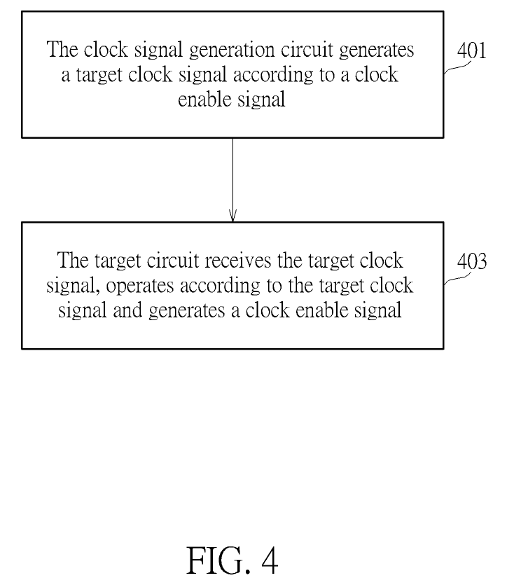

According to the aforementioned embodiments, a signal clock generation method can be obtained. The method is applied to a clock self-control circuit (e.g., the clock self-control circuits 100 and 200 in FIG. 1 and FIG. 2 ) comprising a clock signal generation circuit and a target circuit. FIG. 4 is a flow chart illustrating a clock signal generation circuit according to one embodiment of the present invention, which comprises:

### Step 401

The clock signal generation circuit generates a target clock signal (e.g., target clock signal CLK_T) according to a clock enable signal (e.g., clock enable signal En).

### Step 403

The target circuit receives the target clock signal, operates according to the target clock signal and generates a clock enable signal.

If the clock self-control circuit comprises a timing adjustment circuit 201 as shown in FIG. 2, the clock signal generation method further comprises: using the timing adjustment circuit to extend a trigger time interval of the clock signal generation circuit. The time interval represents a time interval in which the clock signal generation circuit can be triggered by the clock enable signal to generate the target clock signal.

As mentioned above, conventional clock gating circuits cannot be turned off during circuit operation, and thus cannot stop generating clock signals. Alternatively, in order to turn off the clock gating circuit, the clock gating circuit is usually at the end of the clock tree. In this case, even if the clock gating circuit is turned off, the energy consumption of the circuit that can be reduced is very limited. In view of the above embodiments, the self-control circuit provided by the present invention can control the generation of the required clock signal in the functional mode. In this case, the clock gating circuit does not need to be set at the end of the clock tree, so the power consumption can be efficiently reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A clock self-control circuit, comprising:
a clock signal generation circuit, configured to generate a target clock signal according to a clock enable signal; and
a target circuit, configured to receive the target clock signal, and configured to operate according to the target clock signal and to generate the clock enable signal.

2. The clock self-control circuit of claim 1, further comprising:
a timing adjustment circuit, configured to extend a trigger time interval of the clock signal generation circuit, wherein the trigger time interval represents a time interval in which the clock signal generation circuit can be triggered by the clock enable signal.

3. The clock self-control circuit of claim 2, wherein the timing adjustment circuit is a delay circuit, wherein the target circuit generates the clock enable circuit in a first time period, wherein the first time period has a first predetermined time interval, wherein the timing adjustment circuit controls the clock signal generation circuit to receive the clock enable signal in a second time period after the first time period, wherein a specific signal edge of the clock enable signal triggers generation of the target clock signal in a second predetermined time interval of the second time period.

4. The clock self-control circuit of claim 3, wherein the timing adjustment circuit is a D flip flop.

5. The clock self-control circuit of claim 1, wherein the clock signal generation circuit is a clock gating circuit.

6. The clock self-control circuit of claim 1, wherein the target circuit can selectively operates in an functional mode and a non-functional mode, wherein the target clock signal is a clock signal which the target circuit uses in the functional mode.

7. The clock self-control circuit of claim 1, wherein the target circuit comprises a plurality of logic components.

8. The clock self-control circuit of claim 1, wherein the target circuit comprises a state machine, wherein the target circuit generates the clock enable signal according to a state of the state machine.

9. The clock self-control circuit of claim 8, wherein the target circuit can selective operates in an functional mode and a non-functional mode, wherein the target circuit generates the clock enable circuit to control the clock signal generation circuit to generate the target clock signal when the state machine represents that the target circuit is in the functional mode.

10. A clock signal generation method, applied to a clock self-control circuit comprising a clock signal generation circuit and a target circuit, comprising:
the clock signal generation circuit generating a target clock signal according to a clock enable signal; and
the target circuit receiving the target clock signal, operates according to the target clock signal and generates the clock enable signal.

11. The clock signal generation method of claim 10, wherein the clock self-control circuit further comprises a timing adjustment circuit, wherein the clock signal generation method further comprises:
the timing adjustment circuit extending a trigger time interval of the clock signal generation circuit, wherein the trigger time interval represents a time interval in which the clock signal generation circuit can be triggered by the clock enable signal.

12. The clock signal generation method of claim 11, wherein the timing adjustment circuit is a delay circuit, wherein the clock signal generation method further comprises:
the target circuit generating the clock enable circuit in a first time period, wherein the first time period has a first predetermined time interval;
the timing adjustment circuit controlling the clock signal generation circuit to receive the clock enable signal in a second time period after the first time period, wherein a specific signal edge of the clock enable signal triggers generation of the target clock signal in a second predetermined time interval of the second time period.

13. The clock signal generation method of claim 12, wherein the timing adjustment circuit is a D flip flop.

14. The clock signal generation method of claim 10, wherein the clock signal generation circuit is a clock gating circuit.

15. The clock signal generation method of claim 10, wherein the clock signal generation method further comprises:
the target circuit selectively operates in a functional mode and a non-functional mode, wherein the target clock signal is a clock signal which the target circuit uses in the functional mode.

16. The clock signal generation method of claim 10, wherein the target circuit comprises a plurality of logic components.

17. The clock signal generation method of claim 10, wherein the target circuit comprises a state machine, wherein the clock signal generation method further comprises:
the target circuit generating the clock enable signal according to a state of the state machine.

18. The clock signal generation method of claim 17, wherein the target circuit can selective operates in an functional mode and a non-functional mode, wherein the clock signal generation method further comprises:
the target circuit generating the clock enable circuit to control the clock signal generation circuit to generate the target clock signal when the state machine represents that the target circuit is in the functional mode.
